(19) United States
(12) Patent Application Publication
(10) Pub. No.: US 2013/0299936 A1
(43) Pub. Date: Nov. 14, 2013

(54) AVALANCHE PHOTODIODE AND METHOD FOR MANUFACTURING THE SAME

(71) Applicants: Ryota Takemura, Tokyo (JP); Eitaro Ishimura, Tokyo (JP)

(72) Inventors: Ryota Takemura, Tokyo (JP); Eitaro Ishimura, Tokyo (JP)

(73) Assignee: Mitsubishi Electric Corporation, Tokyo (JP)

(21) Appl. No.: 13/745,957

(22) Filed: Jan. 21, 2013

(30) Foreign Application Priority Data
May 10, 2012 (JP) 2012-108577

(51) Int. Cl. H01L 31/107; H01L 31/18

(52) U.S. Cl. CPC H01L 31/107; H01L 31/18
USPC 257/458; 438/91

(57) ABSTRACT

An avalanche photodiode includes a substrate; an avalanche multiplying layer, a p-type electric field controlling layer, a light-absorbing layer, and a window layer sequentially laminated on the substrate. A p-type region is present in parts of the window layer and the light-absorbing layer. Carbon is the dopant of the electric field controlling layer. Zn is the dopant of the p-type region. A bottom face of the p-type region is closer to the substrate than is an interface between the light-absorbing layer and the window layer.

### BACKGROUND OF THE INVENTION

1. Field of the Invention

The present invention relates to an avalanche photodiode used in optical fiber communications, and a method for manufacturing the same.

2. Background Art

An avalanche diode provides a light-absorbing layer and an avalanche multiplying layer. When a light enters into a light-absorbing layer, electron-hole pairs occur. When they become carriers and reach the avalanche multiplying layer, carrier multiplication occurs like an avalanche. Since the incident light can be amplified and taken out as signals thereby, avalanche diodes are frequently used in long-distance optical communications or the like that receive weak optical signals.

In order to cause avalanche multiplying, a high electric field must be applied to the avalanche multiplying layer. However, if a high electric field is applied to the light-absorbing layer, a tunnel breakdown is generated on the light-absorbing layer. Therefore, an electric field controlling layer to control the distribution of the electric field so that a high electric field is applied only to the avalanche multiplying layer is provided between the avalanche multiplying layer and the light-absorbing layer. In general, the electric field strength in the avalanche multiplying layer is preferably 600 kV/cm or higher, and the electric field strength in the light-absorbing layer is preferably 200 kV/cm or lower.

Depending on the material of the avalanche multiplying layer, which of generated electrons and holes are easily multiplied differ. Since low noise and quick response are desired in the use of high-speed optical communications, the materials that easily multiply electrons are frequently used for the avalanche multiplying layer. In these cases, the electric field controlling layer is made to be p-type, and for its dopant, Zn or Be easily doped as their dopant is frequently used.

On the upper portion of the light-absorbing layer, window layers transmitting light are frequently laminated. The window layers consist of materials having a wide band gap for lowering dark current. On a part of the window layer, a p-type region for electrical contacting is formed (for example, refer to Japanese Patent No. 4166560).

### SUMMARY OF THE INVENTION

Be or Zn doped into the electric field controlling layer has a high diffusion constant due to heat. For this reason, these diffuse into un-doped layers at both ends of the electric field controlling layer due to the heat treatment during the process, and highly affect the characteristics of the avalanche photodiode. Therefore, the thermal history during the process had to be as low as possible. The heat treatment temperature during the process is generally 450 to 540° C. (for example, refer to Japanese Patent Laid-Open No. 2-20074 and Japanese Patent No. 4103885).

As a p-type dopant having a low diffusion constant, carbon has been known (for example, refer to National Publication of International Patent Application No. 2005-516414, European Patent Application Laid-Open No. 2073277 and Japanese Patent Laid-Open No. 2011-243675). Therefore, for elongating the heat treatment time, the usage of carbon has been considered as the dopant of electric field controlling layer. However, doping itself of carbon is more difficult than that of Be or Zn. Consequently, for succeeding the doping concentration required in the electric field controlling layer, the growing temperature of the electric field controlling layer must be lowered than that of other layers, such as the light-absorbing layer or the like. Thereby, unnecessary elements such as hydrogen have been taken in the electric field controlling layer. Since the unnecessary elements easily move during the operation of the avalanche photodiode and affect the activation of carriers, they have been the cause of age variation in characteristics such as breakdown voltages.

In addition, in the conventional avalanche photodiode, since the discontinuity of the energy level of a valence band and conduction band in the interface between the window layer and the light-absorbing layer was large and the movement of carriers was inhibited, there was a problem of poor high-speed response.

In view of the above-described problems, an object of the present invention is to provide an avalanche photodiode and a method for manufacturing the same which can improve the high-speed response and reduce the time variation of the characteristics.

According to the present invention, an avalanche photodiode comprises: a substrate; an avalanche multiplying layer, a p-type electric field controlling layer, a light-absorbing layer, and a window layer sequentially laminated on the substrate; and a p-type region on parts of the window layer and the light-absorbing layer. Carbon is used as a dopant of the electric field controlling layer. Zn is used as a dopant of the p-type region. A bottom face of the p-type region is below an interface between the light-absorbing layer and the window layer.

The present invention makes it possible to improve the high-speed response and reduce the time variation of the characteristics.

Other and further objects, features and advantages of the invention will appear more fully from the following description.

### BRIEF DESCRIPTION OF THE DRAWINGS

FIG. 1 is a sectional view showing an avalanche photodiode according to a first embodiment of the present invention.

FIG. 2 is a sectional view showing an avalanche photodiode according to the comparative example.

FIG. 3 is a graph showing the energy level of the avalanche photodiode according to the comparative example.

FIG. 4 is a graph showing the energy level of the avalanche photodiode according to the first embodiment of the present invention.

FIG. 5 is a sectional view showing an avalanche photodiode according to a second embodiment of the present invention.

FIG. 6 is a sectional view showing an avalanche photodiode according to a third embodiment of the present invention.

FIG. 7 is a sectional view showing an avalanche photodiode according to a fourth embodiment of the present invention.

FIG. 8 is a sectional view showing an avalanche photodiode according to a fifth embodiment of the present invention.

### DETAILED DESCRIPTION OF THE PREFERRED EMBODIMENTS

An avalanche photodiode and a method for manufacturing the same according to the embodiments of the present invention will be described with reference to the drawings. The same components will be denoted by the same symbols, and the repeated description thereof may be omitted.

### First Embodiment

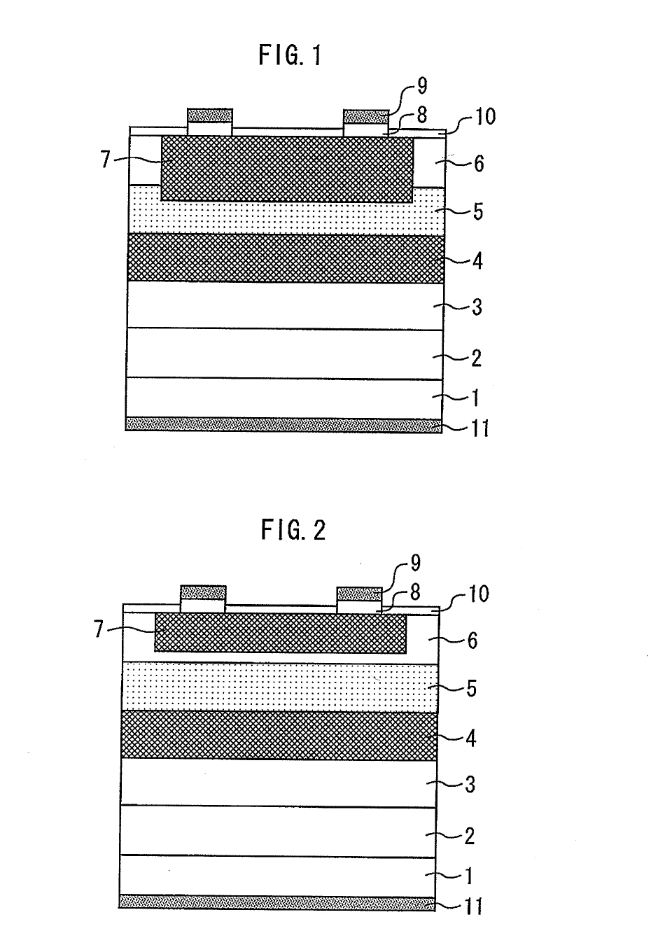

FIG. 1 is a sectional view showing an avalanche photodiode according to a first embodiment of the present invention. On an n-type InP substrate 1, an n-type AlInAs buffer layer 2, an AlInAs avalanche multiplying layer 3, a P-type AlInAs electric field controlling layer 4, an un-doped light-absorbing layer 5, and a window layer 6 are sequentially laminated. As the dopant of the P-type AlInAs electric field controlling layer 4, carbon is used.

The carrier concentration of the n-type AlInAs buffer layer 2 is 5×10¹⁸ cm⁻³ or lower, and the layer thickness is 0.1 to 1 μm. The carrier concentration of the AlInAs avalanche multiplying layer 3 is 0.1×10¹⁵ to 8×10¹⁵ cm⁻³, and the layer thickness is 0.05 to 0.5 μm. The carrier concentration of the p-type AlInAs electric field controlling layer 4 is 2×10¹⁷ to 2×10¹⁸ cm⁻³, and the layer thickness is 0.01 to 0.2 μm. The layer thickness of the un-doped light-absorbing layer 5 is 0.5 to 2.5 μm. The window layer 6 is un-doped, or doped in n-type, and the carrier concentration is 3×10¹⁶ cm³ or lower, and the layer thickness is 0.5 to 2 μm.

A p-type region 7 is provided on parts of the window layer 6 and the un-doped light-absorbing layer 5. As the dopant of the p-type region 7, Zn is used. Zn diffusion reaches to the un-doped light-absorbing layer 5, and the bottom face of the p-type region 7 is below the interface between the un-doped light-absorbing layer 5 and the window layer 6.

An InGaAs contact layer 8 is provided on the p-type region 7, and a P-side electrode 9 is provided so as to contact the InGaAs contact layer 8. On the region other than the InGaAs contact layer 8, the upper face of the window layer 6 is covered with SiN film 10, which is the passivation film and the reflection preventing film. On the back face of the n-type InP substrate 1, an n-side electrode 11 is provided.

Next, a method for manufacturing the avalanche photodiode according to the present embodiment will be described. By the MOCVD (Metal Organic Chemical Vapor Deposition) method or the MBE (Molecular Beam Epitaxy) method, an n-type AlInAs buffer layer 2, an AlInAs avalanche multiplying layer 3, a p-type AlInAs electric field controlling layer 4, an un-doped light-absorbing layer 5, a window layer 6, and an InGaAs contact layer 8 are sequentially formed on an n-type InP substrate 1.

Next, Zn is diffused by a selective thermal diffusing method using an insulating film having a circular hole as a mask (solid diffusion of Zn), and the p-type region 7 is formed on parts of the window layer 6 and the un-doped light-absorbing layer 5.

Next, the InGaAs contact layer 8 on the p-type region 7 is etched so as to leave a ring having an approximately 5 μm in width. Then, a SiN film 10 is formed. The thickness d of the SiN film 10 is adjusted so as to be nearly d=λ/4/n to form a reflection preventing film, where n is a refractive index, and X, is a wavelength of an incident light.

Next, a part of the SiN film 10 on the InGaAs contact layer 8 is removed. A p-side electrode 9 is formed by patterning so as to contact with the InGaAs contact layer 8. Thereafter, the back face of the n-type InP substrate 1 is polished to form the n-side electrode 11.

Subsequently, the operation of the avalanche photodiode according to the present embodiment will be described. When a light is incident to the un-doped light-absorbing layer 5 in the condition where a plus voltage is applied to the n-side electrode 11 and a minus voltage is applied to the p-side electrode 9, electrons and holes are generated. Since the generated electrons are moved to the side of the n-type InP substrate 1, they reach the AlInAs avalanche multiplying layer 3 after passing through the p-type AlInAs electric field controlling layer 4. The operations where an electric field sufficiently high to cause multiplication is applied to the AlInAs avalanche multiplying layer 3, the entered electrons create electron-hole pairs, and further generated electrons create other electron-hole pairs are repeated to multiply signals.

Next, the effect of the present embodiment will be described by comparing with a comparative example. FIG. 2 is a sectional view showing an avalanche photodiode according to the comparative example. In the comparative example, Be or Zn are used as the dopant of the p-type AlInAs electric field controlling layer 4. Since the carrier diffusion of the p-type AlInAs electric field controlling layer 4 is required to be suppressed, the Zn diffusing time cannot be long. In addition, since the p-type region 7, to which the electric field is strongly applied, improves the reliability by protecting by a layer with a large band gap, the p-type region 7 is provided only in the window layer 6. Therefore, the Zn diffusion does not reach the un-doped light-absorbing layer 5.

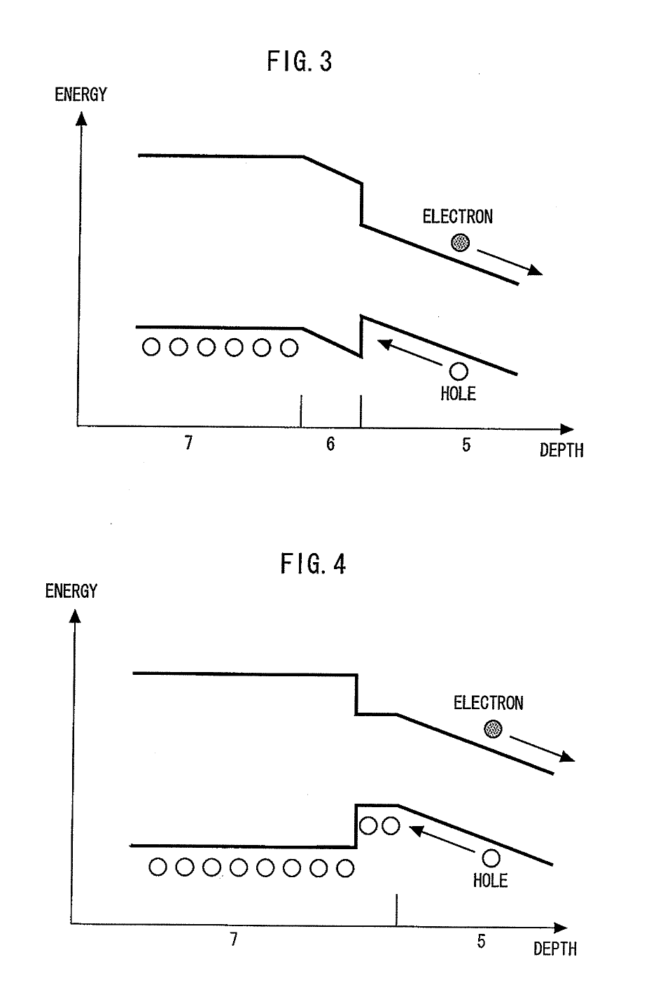

FIG. 3 is a graph showing the energy level of the avalanche photodiode according to the comparative example. In the comparative example, since the discontinuity of the energy-levels of a charged electron band and conduction band in the interface between the window layer 6 and the un-doped light-absorbing layer 5 is large, and the movement of carriers is inhibited, and high-speed responsivity is poor.

FIG. 4 is a graph showing the energy level of the avalanche photodiode according to the first embodiment of the present invention. In the present embodiment, a part of the un-doped light-absorbing layer 5 is made to be p-type. Thereby, since a large number of holes are present in the vicinity of the interface of the un-doped light-absorbing layer 5 and the window layer 6, the energy level difference between the charged electron band and conduction band at the interface is not required to exceed with the drift of carriers, and high-speed response can be elevated.

In a part of Zn reached to the un-doped light-absorbing layer 5, the diffusion speed becomes exponentially high and passes through the un-doped light-absorbing layer 5, and some reaches to the vicinity of the p-type AlInAs electric field controlling layer 4. In the comparative example, the constituents having a high Zn diffusion speed are reciprocally diffused with Be or Zn which is the dopant of the p-type AlInAs electric field controlling layer 4. Therefore, the carrier concentration of the p-type AlInAs electric field controlling layer 4 is markedly lowered, and desired electric field distribution cannot be obtained, and the device may not be able to operate as the avalanche photodiode. On the other hand, in the present embodiment, since carbon is used as the dopant of the p-type AlInAs electric field controlling layer 4, the lowering of the carrier concentration of the p-type AlInAs electric field controlling layer 4 due to interdiffusion does not occur.

Also in the comparative example, for preventing thermal diffusion from the p-type AlInAs electric field controlling layer 4 of Be or Zn having a high diffusion constant, the Zn diffusing time cannot be increased. In the present embodiment, on the other hand, since carbon is used as the dopant of the p-type AlInAs electric field controlling layer 4, the Zn diffusing time can be belonged. Thereby, the thermal history during the process can be increased, and the unnecessary elements such as hydrogen in the p-type AlInAs electric field controlling layer 4 using carbon can be thermally diffused and removed. Furthermore, by reacting the unnecessary elements with the constituent having high Zn diffusion speed, the concentration can be lowered. As a result, the movement of the unnecessary elements at the usage of the avalanche photodiode can be prevented, and the time variation of the characteristics can be lowered.

In addition, if the impurity concentration in the p-type AlInAs electric field controlling layer 4 is lower than 2×10¹⁷ cm⁻³, the layer thickness of the p-type AlInAs electric field controlling layer 4 must be thicker than 0.2 μm to obtain the required relaxation, and the running time of the carriers is increased and the high-speed responsivity becomes poor. It is therefore preferable that the impurity concentration of the p-type AlInAs electric field controlling layer 4 is at least 2×10¹⁷ cm⁻³.

In addition, if the carrier concentration of the p-type AlInAs electric field controlling layer 4 is high, the growing temperature is lowered, and the unnecessary elements such as hydrogen increase. Furthermore, if the carrier concentration is higher than 2×10¹⁸cm⁻³, the layer thickness of the p-type AlInAs electric field controlling layer 4 becomes thinner than 10 nm, and problems in layer thickness control occur. Therefore, the impurity concentration of the p-type AlInAs electric field controlling layer 4 preferably does not exceed 2×10¹⁸cm⁻³.

The constituents having the fast Zn diffusion speed increase when the diffusion temperature is high. Therefore, for reducing the time variation of characteristics, it is preferable that the temperature in the solid-phase diffusion of Zn is higher than 540° C.

InP is used in the substrate, and InP or AlInAs is used in the n-type buffer layer. AlInAs or AIAsSb is used in the avalanche multiplying layer. AlInAs, AlGaInAs, InGaAsP, or InP is used in the electric field control layer. InGaAs or InGaAsP is used in the light-absorbing layer. InP, InGaAsP, AlGaInAs, AlInAs or the like are used in the window layer. However, any materials can be used if the required characteristics in each layer can be obtained, and these materials do not limit the range of the invention. In addition, the n-type buffer layer can be made as the contact layer such as InGaAs; and the substrate can be a semi-insulating substrate such as the Fe-doped substrate.

### Second Embodiment

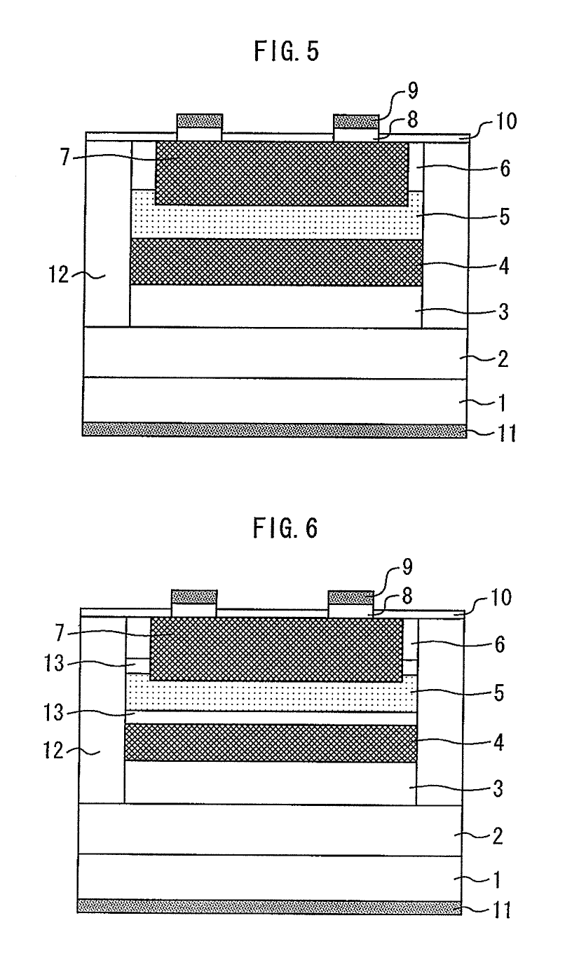

FIG. 5 is a sectional view showing an avalanche photodiode according to a second embodiment of the present invention. The buried semiconductor layer 12 of semi-insulation buries the sides of the AlInAs avalanche multiplying layer 3, the p-type AlInAs electric field controlling layer 4, the un-doped light-absorbing layer 5, and the window layer 6. However, it is enough that the buried semiconductor layer 12 buries at least the un-doped light-absorbing layer 5. The buried semiconductor layer 12 has a wider band-gap than that of the un-doped light-absorbing layer 5.

By the buried semiconductor layer 12, the exposure of the un-doped light-absorbing layer 5 having the narrow band gap is prevented, and the element reliability can be improved. In addition, since the un-doped window layer 6 exists between the p-type region 7 and the buried semiconductor layer 12, the leak current is not increased.

### Third Embodiment

FIG. 6 is a sectional view showing an avalanche photodiode according to a third embodiment of the present invention. A graded layer 13 is provided between the un-doped light-absorbing layer 5 and the adjacent layer. Other constitutions are identical to the constitutions of the second embodiment. Since the discontinuity of the charged electron band and conduction band between the un-doped light-absorbing layer 5 and the adjacent layer becomes smaller and the movement of the carriers become easier thereby, the high-speed response can be improved. In addition, although the graded layers 13 are preferably formed on both sides of the un-doped light-absorbing layer 5, the effect is obtained if there is a graded layer 13 only on one side.

### Fourth Embodiment

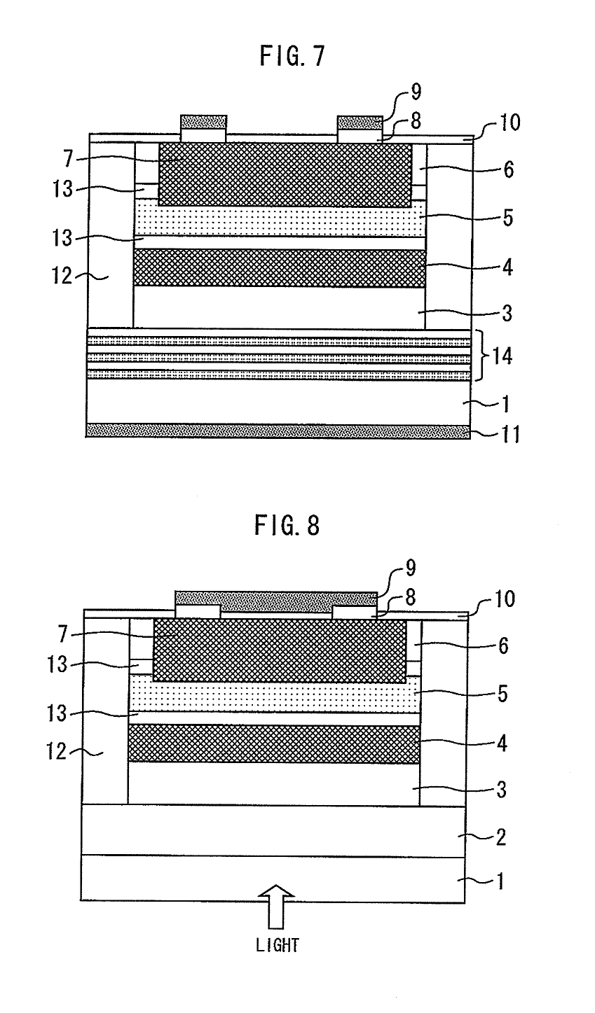

FIG. 7 is a sectional view showing an avalanche photodiode according to a fourth embodiment of the present invention. In place of the n-type AlInAs buffer layer 2, a DBR (Distributed Bragg Reflector) 14 is provided. Other constitutions are identical to the constitutions of the third embodiment. By reflecting the light transmitted through the un-doped light-absorbing layer 5 with DBR 14, and returning the light to the un-doped light-absorbing layer 5, the sensitivity can be elevated.

### Fifth Embodiment

FIG. 8 is a sectional view showing an avalanche photodiode according to a fifth embodiment of the present invention. This avalanche photodiode is of a back-face incident type. In this case, different from the front-face incident type, the p-type lnGaAs contact layer 8 and the p-side electrode 9 are not required to be a ring form. Although there is a region that is hidden in the ring-like p-side electrode 9 and the light cannot be incident in the case of the front-face incident type, the light becomes received by making it to be the back-face incident type, and the size of the light-receiving region can be expanded. In addition, when the substrate is an Fe-doped substrate, the absorption of light into the substrate decreases, and the quantum efficiency can be improved.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2012-108577, filed on May 10, 2012, including specification, claims, drawings, and summary, on which the Convention priority of the present application is based, is incorporated herein by reference in its entirety.

1. An avalanche photodiode comprising:
a substrate;
an avalanche multiplying layer, a p-type electric field controlling layer, a light-absorbing layer, and a window layer sequentially laminated on the substrate; and
a p-type region in parts of the window layer and the light-absorbing layer, wherein
the electric field controlling layer is doped with carbon,
the p-type region is doped with zinc, and
a bottom face of the p-type region is closer to the substrate than is an interface between the light-absorbing layer and the window layer.

2. The avalanche photodiode according to claim 1, wherein dopant impurity concentration in the electric field controlling layer is at least 2×10¹⁷ cm⁻³ and does not exceed 2×10¹⁸ cm⁻³.

3. The avalanche photodiode according to claim 1, further comprising a buried semiconductor layer burying a side of the light-absorbing layer and having 4as a wider band-gap than the light-absorbing layer.

4. A method for manufacturing an avalanche photodiode comprising:
sequentially forming an avalanche multiplying layer, a p-type electric field controlling layer, a light-absorbing layer, and a window layer on a substrate; and
forming a p-type region in parts of the window layer and the light-absorbing layer by diffusing Zn in the window layer and the light-absorbing layer, wherein
the electric field controlling layer is doped with carbon, and
a bottom face of the p-type region is closer to the substrate than an interface between the light-absorbing layer and the window layer.

5. The method for manufacturing an avalanche photodiode according to claim 4, including diffusing the Zn at a temperature higher than 540° C.
